(19) United States
(12) Patent Application Publication
(10) Pub. No.: US 2001/0026438 A1
(43) Pub. Date: Oct. 4, 2001

(54) Electric power module and method for making same

(76) Inventor: Olivier Dominique Ploix, Boulogne (FR)

Correspondence Address: LARSON & TAYLOR, PLC, 1199 NORTH FAIRFAX STREET, SUITE 900, ALEXANDRIA, VA, 22314, US

(21) Appl. No.: 09/737,855

(22) Filed: Mar. 5, 2001

(30) Foreign Application Priority Data
Dec. 21, 1999 (FR) 99 16160

(51) Int. Cl. H05K 7/20

(52) U.S. Cl. 361/688

(57) ABSTRACT

An electric module comprising at least one conductive connecting bar supporting at least one electronic power component, the contacts of which are supported on a printed circuit board adjacent to the bar and on a portion of a power-conducting bar underneath the board, a heat-cured insulating material coating at least the adjacent edges of the board and the conductive bars in order to hold the top faces of the bar, the board and the portion of the bar in predetermined relative positions.

### FIELD OF THE INVENTION

The present invention relates to improvements made to the structure and manufacture of electric power modules which comprise one or several electronic power components, such as power transistors. Such modules specifically, though not exclusively, find applications in the automotive industry where electronic circuits are used to supply components or various operational elements (for example an electric motor driving an electric pump unit for power-assisted steering on a motor vehicle).

### DESCRIPTION OF THE PRIOR ART

These modules are placed in a high ambient temperature, which makes evacuation of the heat dissipated by the electronic power component or components more difficult.

Electric modules have already been proposed in which the design is based on a metal substrate, in particular of aluminium or an aluminium alloy, the component parts (printed circuit board, equipotential conductive plates, . . . ) being fixed in particular by means of screws, pins or rivets to keep them applied tightly one against the other to produce good heat and/or electric conduction.

For users, however, it seems desirable to reduce the weight and cost of these modules as far as possible, as well as the number of component parts.

In addition, the structure of the module must be compatible with the electronic components with which it is fitted. In this respect, electronic power components are generally in the form of a casing having at least one flat face which can be placed against a support onto which this casing is fixed (in particular by welding) in order to ensure, firstly, electric conduction and, secondly, discharge of the heat. Extending from this casing are several contacts in the form of strips designed to have respective support surfaces which extend at predetermined levels relative to said support face of the casing (often these surfaces of the contact strips are coplanar with the support face of the casing). When assembling the component parts making up the structure of the module, the surfaces intended to receive the supporting faces of the casings of the components and the support face of the respective contact therefore have to be correctly positioned relative to one another so that the power components can then be correctly mounted (in particular by welding) and fixed.

### SUMMARY OF THE INVENTION

Accordingly, the objective of the present invention is to provide an electric power module which better meets the various requirements than those presently known whilst conserving a reduced heat resistance within the heat dissipation circuit, enabling the electronic power components to admit quick heating peaks.

To these ends, the invention proposes an electric module which comprises:

at least one bar providing an equipotential connection made from an electrically conductive material;

at least one electronic power component in direct contact with said conductive bar;

a printed circuit board on which electronic components of the module having reduced heat dissipation are mounted, this board being arranged adjacent to said conductive bar with its top face disposed in a predetermined position relative to that of said conductive bar;

at least one conductive bar through which a power current flows, underneath the printed circuit board and having at least one portion with a top face adjacent to said conductive bar and in a predetermined position relative to that of said conductive bar;

said power component having contacts connected respectively to a printed circuit of said printed circuit board and to the top face of said portion of the power-conducting bar;

and top and bottom layers made from a heat-cured insulating material covering said conductive bar, printed circuit board and power-conducting bar in their mutually adjacent zones in order to impart rigidity to the unit thus formed and to maintain the relative positions of said surfaces to guarantee the reliability and electrical continuity of the contacts of the power component.

Advantageously, the printed circuit board and the power-conducting bar are joined to one another by inserting a polymerised, adhesive, electrically insulating film in between.

In one compact embodiment, the printed circuit board has conductive tracks on its two faces to provide connections with the conductive bar(s) and/or to mount components on the bottom face where it extends beyond the power-conducting bar(s). Always in order to provide a more compact structure in which the component parts can be at least partly nested one inside the other, it is provided that the printed circuit board has cut-out portions and/or slots to provide a passage for portions of the power-conducting bar(s) with a view to allow a contact to be made with an electrical power component supported by the conductive bar.

In more complex and larger structures, it can be provided that the module has several conductive bars electrically independent of one another and arranged adjacent to one another and/or several power-conducting bars electrically independent of one another and adjacent to one another.

In order to ensure that the various component parts of the structure are correctly positioned relative to one another and obtain a rigid unit at the end, it is provided that the heat-cured insulating material is applied in the form of strips which overlap at least adjacent zones of the printed circuit board, the conductive bar(s) and the power-conducting bar(s), filling the spaces between this board and these bars. Advantageously, however, it can provided that the cured insulating material covers the entire bottom surface of the conductive bars and power-conducting bars and covers the top surface of the printed circuit board and the conductive bar except for the electronic components mounting areas, so that the polymerised material extends across large surfaces and adheres more readily to the components arranged underneath, so imparting increased mechanical strength to the unit and affording better protection of the metal surfaces against dirt and the risk of short-circuiting.

In one practical embodiment, the top faces of the printed circuit board, the conductive bar and said portion of the power-conducting bar are retained in a substantially mutually coplanar position.

According to another of its aspects, the invention proposes a specific method of manufacturing the electric module described above, said method being characterised in that:

a printed circuit board and at least one power-conducting bar are assembled superimposed with an electrical insulating sheet, which is adhesive on both sides, placed in between,

at least one conductive bar and said assembly comprising the printed circuit board and at least one power-conducting bar are juxtaposed,

at least strips of adhesive insulating material are applied, overlapping at least adjacent zones of the printed circuit board, the conductive bar and the power-conducting bar but leaving free those areas intended to receive electronic components, and the unit is clamped so that given surfaces of the printed circuit board, the conductive bar and the power-conducting bar are maintained in given relative positions;

the unit is heated to polymerise and cure the adhesives and form a monobloc module,

and at least one electronic power component is mounted, in particular by welding, on the conductive bar in such a manner that its contacts rest on the printed circuit board and on one face of the power-conducting bar, as well as electronic components with a reduced heat dissipation on the printed circuit board.

Due to the features proposed by the invention, an improved electric module is provided, which, whilst conserving the heat and electrical conducting properties needed to operate correctly, is also more rigid and in which component parts of the structure are correctly positioned relative to one another enabling electric power components to be assembled as required.

In addition, these advantages are obtained whilst eliminating the need for a metal substrate and fixing screws, pins or rivets required in prior modules, thereby considerably reducing the weight of the electric module, the number of component parts needed to make it and its cost.

### BRIEF DESCRIPTION OF THE DRAWINGS

The invention will be more readily understood from the detailed description of embodiments below, given purely by way of example and not restrictive in any respect, and with reference to the appended drawings, in which:

FIG. 1 is a plan view, from above, of a part of an electric module designed as proposed by the invention;

FIGS. 2 to 4 are views in cross section along the lines II-II, III-III and IV-IV of FIG. 1 respectively;

FIG. 5 is a perspective view of an electric module designed as proposed by the invention, from which the printed circuit board has been removed;

FIG. 6 is a perspective view of the electric module illustrated in FIG. 5 with the printed circuit board mounted in position; and

FIG. 7 is a perspective view of a different embodiment of the electric module (printed circuit board not illustrated) fitted with a plurality of conductive bars.

### DETAILED DESCRIPTION OF THE INVENTION

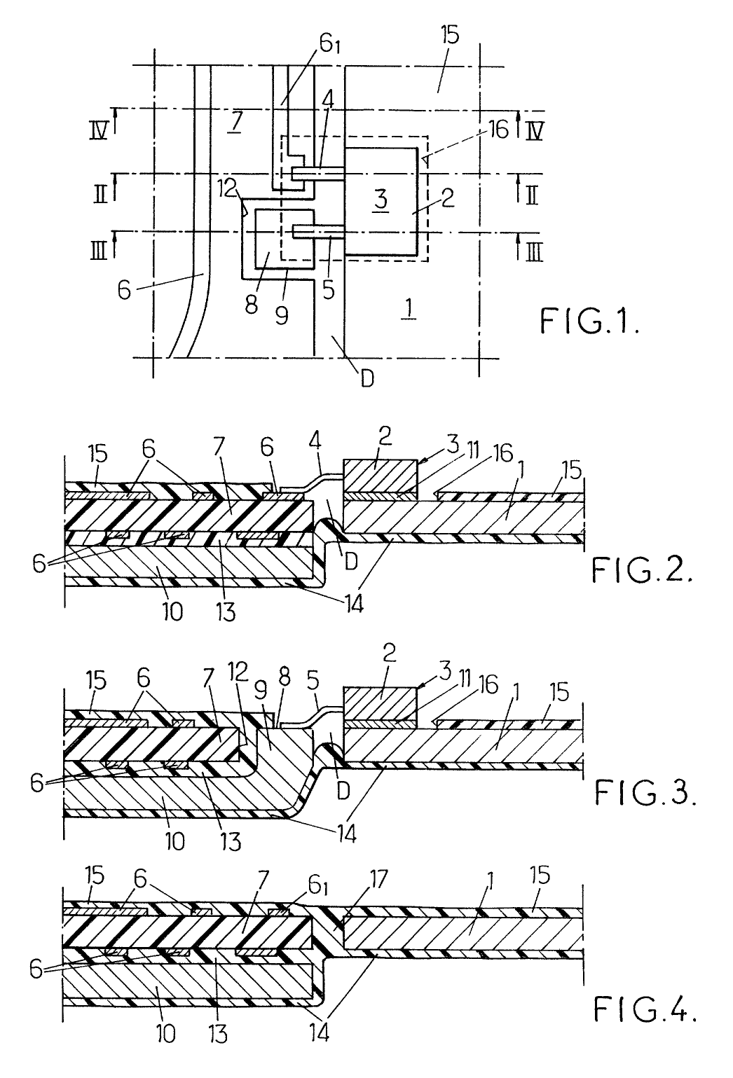

Reference will firstly be made at FIGS. 1 to 4, which illustrate a part of an electric module of a design proposed by the invention. The module comprises at least one conductive equipotential plate or bar 1 on an edge of the top face of which the casing 2 of an electronic power component 3 (for example a transistor, a thyristor, . . . ) is fixed, in particular by welding 11, so that this component (which has a metal casing and forms one of the electrodes) is in close heat and electrical conducting contact with the conductive bar 1.

The electronic power component 3 has two contacts 4 and 5 in the form of strips or pins, projecting laterally beyond the edge of the conductive bar 1.

As may be seen from FIGS. 1 and 2, one of the contacts 4 is supported by its free end and is welded onto a track 6₁ of a printed circuit board 7. The printed circuit board 7 bears a plurality of copper tracks 6 both on its top face and on its bottom face and is provided on one and/or the other of its faces with electronic components having a reduced heat dissipation (not illustrated).

As may be seen from FIGS. 1 and 3, the other contact 5 of the component 3 is supported by its free end and is welded onto the top face 8 of a portion 9 of a power-conducting plate or bar 10 disposed, at least partially, underneath the printed circuit board 7. Said portion 9 of the power-conducting bar 10 may be formed by a projection directed towards the top of said bar (for example a pad cut out from the bar and bent upwards). In order for this projection 9 to be correctly positioned facing the conductive bar 1 and the power component 3, a cut-out portion 12 (or a slot if necessary) is provided in the edge of the printed circuit board 7 in which said projection 9 appears.

In the example illustrated, the power component 3 is such designed that the supporting faces of the ends of its contacts 4 and 5 are substantially coplanar with the supporting face of its casing 2, by means of which it rests on the conductive bar 1. Accordingly, the top face of the printed circuit board 7 with said track 6₁, on the one hand, and the top face 8 of the portion 9 of the power-conducting bar 10, on the other hand, must be substantially mutually coplanar and in addition must be substantially coplanar with the top face of the conductive bar 1.

Of course, relative positions other than the coplanar position would also be conceivable under the same conditions, depending on the shape of the electronic power component 3.

In order to keep the printed circuit board 7 and the two conductive bars 1 and 10 firmly joined in the requisite position relative to one another, it is provided that:

the printed circuit board 7 and the power-conducting bar 10 are joined by an electrical insulating film or sheet with adhesive on both sides, which is polymerised by heat treatment to produce a rigid insulating layer 13 mechanically joining the board 7 and the plate 10;

adhesive insulating strips are applied straddling the gap D between the facing edges of the printed circuit board 7, the power-conducting bar 10 with its projecting portions 9 and the conductive bar 1; the strips are disposed on the top but leaving free any areas provided for electronic power components 3 and their contacts 4 and 5, and optionally any areas provided for electronic components with a low heat dissipation on the printed circuit board; the facing strips underneath extend continuously; these strips are polymerised by heat treatment, causing them to flow into the free spaces, which they fill, and harden, mechanically joining the board 7 and the bars 1 and 10, locking them in their requisite mutual positions.

By preference, as illustrated in FIGS. 1 to 4, these are not simple strips that are applied straddling the gap D but films or sheets which cover the entire bottom surface and the entire top surface except for component locations.

After polymerisation, it has been formed a bottom, rigid insulating layer 14, a top rigid insulating layer 15 having free areas 16 for the electronic components and a filling 17 in the gap 12 (optionally with the exception of the area underneath the pins 4 and 5 of the component 3), which can be seen in FIG. 4 on the section along the line IV-IV of FIG. 1 outside of the free area 16.

The features according to the invention enable units to be assembled comprising a large number of electronic power components, even a plurality of conductive bars and/or power-conducting bars, in the form of compact and perfectly rigid modules, which finally form prefabricated integral units that are easy to fit in a motor vehicle, for example.

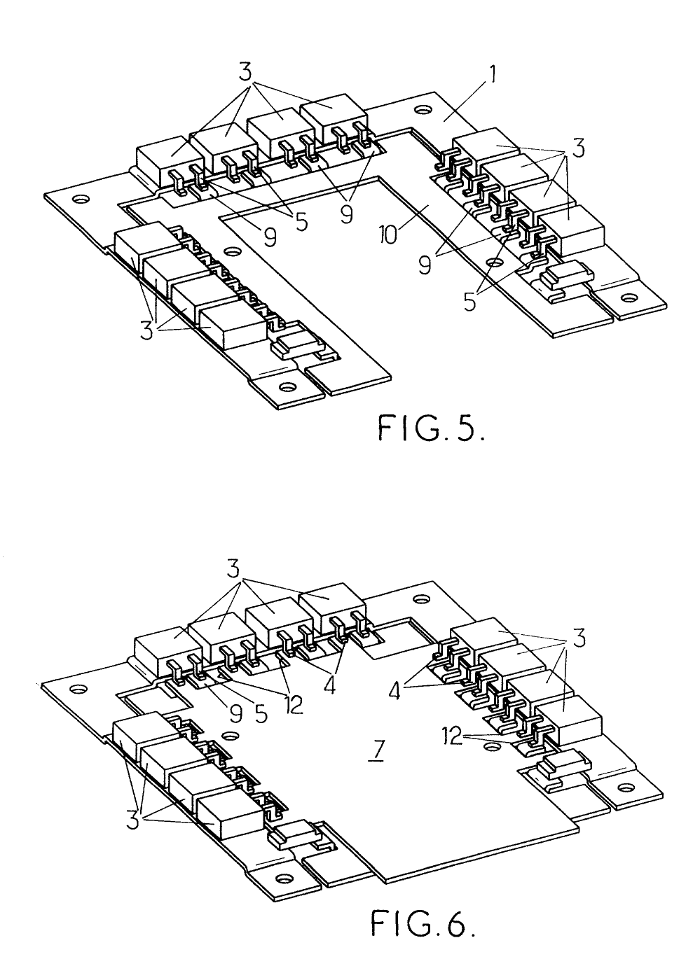

In order to provide a clear understanding, FIGS. 5 and 6 illustrate one possible example of a unit assembled as proposed by the invention, but not yet finished (the polymerised layers and the components with low heat dissipation on the printed circuit board are missing in particular) so as to make the drawings easier to read.

FIG. 5 illustrates a conductive bar 1 which extends in a U shape and which bears a plurality of electronic power components 3, the contacts of which are directed towards the inside of the U. Extending inside the U and slightly lower than the conductive plate 1 is the power-conducting bar 10 (which is visible because the printed circuit board is not illustrated), which also extends in a U and has projections 9 (provided as cut-out sections folded up) on its outer edge standing up underneath the contacts 5 of the components 3.

The diagram of FIG. 5 is completed in FIG. 6, which shows the printed circuit board 7 (the tracks are not illustrated), the edge of which has cut-out sections 12 leaving a free passage for said projections 9. The contacts 4 of the power components 3 are supported on the board 7.

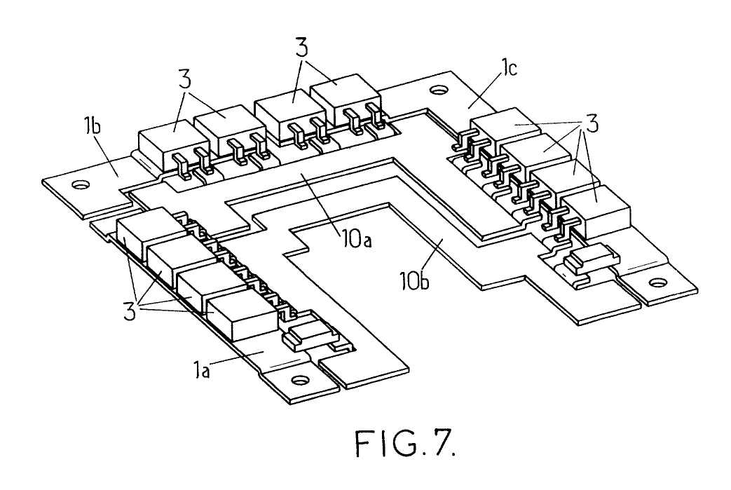

FIG. 7 illustrates, under the same conditions as FIG. 5, another embodiment having a plurality of conductive bars 1 and power-conducting bars 10. The single conductive bar 1 of FIG. 5 has been replaced by several (three in the example illustrated) sections of conductive bars 1a, 1b, 1c supporting the electronic power components 3, the casings of which can then be brought to different potentials. Similarly, the single power-conducting bar 10 of FIG. 5 has been replaced by several (two in the example illustrated) sections of power-conducting bars 10a and 10b, the shape of which is designed to join the contacts 5 of the requisite components 3.

Of course, more complex layouts would be conceivable and the conductive bars 1 and/or the power-conducting bars 10 might be nested one inside the other and optionally overlap; the polymerisable, adhesive insulating strips will then be placed on the requisite areas to avoid short-circuits and impart rigidity to the unit.

From the explanations given above, it can be understood that an electric module according to the invention can be manufactured under conditions that will bring a considerable cost saving whilst producing a mechanically strong, rigid monobloc unit. Such a module is made along the following steps:

a printed circuit board and at least one power-conducting power bar are assembled superimposed with an electrical insulating sheet with adhesive on both sides placed in between,

said assembly and at least one conductive plate are juxtaposed,

at least strips of adhesive electrical insulating material are disposed straddling at least adjacent zones of the printed circuit board, the power-conducting bar and the conductive bar, but leaving free areas intended to receive electronic components, and the unit is clamped so that given surfaces of the printed circuit board, the power-conducting bar and the conductive bar are held in predetermined relative positions,

the unit is heated to soften the adhesive insulating materials causing them to take up the free spaces, after which they are allowed to polymerise by curing so as to produce a rigid monobloc unit,

and, finally, at least one electronic power component is mounted on the conductive bar, in particular by welding, so that its contacts rest on the printed circuit board and on a face of the power-conducting bar, as well as electronic components with a reduced heat dissipation on the printed circuit board.

The module thus obtained has good mechanical rigidity and the conductive bars in particular, made from a metal that is a good electrical conductor (for example copper or with a copper base) with a high expansion coefficient, are mechanically retained under conditions whereby, in spite of the ambient atmosphere of high temperature due to the proximity of the vehicle engine, these bars are prevented from deforming, which would place a high degree of stress on the contacts of the power components, risking breakage of these contacts.

What is claimed is:

1. An electric power module comprising:
at least one bar providing an equipotential connection made from an electrically conductive material;
at least one electronic power component in direct contact with said conductive bar;
a printed circuit board on which electronic components of the module having reduced heat dissipation are mounted, this board being arranged adjacent to said conductive bar with its top face disposed in a predetermined position relative to that of said conductive bar;
at least one conductive bar through which a power current flows, underneath the printed circuit board and having at least one portion with a top face adjacent to said conductive bar and in a predetermined position relative to that of said conductive bar;
said power component having contacts connected respectively to a printed circuit of said printed circuit board and to the top face of said portion of the power-conducting bar;
and top and bottom layers made from a heat-cured insulating material covering said conductive bar, printed circuit board and power-conducting bar in their mutually adjacent zones in order to impart rigidity to the unit thus formed and to maintain the relative positions of said surfaces to guarantee the reliability and electrical continuity of the contacts of the power component.

2. An electric module as claimed in claim 1, wherein the printed circuit board and the power-conducting bar are joined to one another by inserting a polymerised, adhesive, electrical insulating film in between.

3. An electric module as claimed in claim 1, wherein the printed circuit board has conductive tracks on its two faces to provide connections to the conductive bar(s) and/or to mount components on the bottom face where it extends beyond the power-conducting bar(s).

4. An electric module as claimed in claim 1, wherein the printed circuit board has cut-out sections and/or slots to provide a passage for portions of the power-conducting bar(s) with a view to allow a connecting contact with an electronic power component supported by the conductive bar.

5. An electric module as claimed in claim 1, having several juxtaposed conductive bars electrically independent of one another.

6. An electric module as claimed in claim 1, having several juxtaposed power-conducting bars electrically independent of one another.

7. An electric module as claimed in claim 1, wherein the heat-cured insulating material is applied in the form of strips which overlap at least adjacent zones of the printed circuit board, the conductive bar(s) and the power-conducting bar(s), filling any gaps between this board and these bars.

8. An electric module as claimed in claim 7, wherein the cured insulating material covers the entire bottom surface of the conductive and power-conducting bars and covers the top surface of the printed circuit board and the conductive bar except for the electronic components mounting areas.

9. An electric module as claimed in claim 1, wherein the top faces of the printed circuit board, the conductive bar and said portion of the power-conducting bar are retained in a mutually substantially coplanar position.

10. A method of manufacturing an electric module as claimed in claim 1, having the following steps:
a printed circuit board and at least one power-conducting bar are assembled superimposed with an electrical insulating sheet, which is adhesive on both sides, placed in between,
at least one conductive bar is placed adjacent to said assembly comprising the printed circuit board and at least one power-conducting bar,
at least strips of adhesive insulating material are applied, overlapping at least adjacent zones of the printed circuit board, the conductive bar and the power-conducting bar but leaving free those areas intended to receive electronic components, and the unit is clamped so that given surfaces of the printed circuit board, the conductive bar and the power-conducting bar can be maintained in given relative positions,
the unit is heated to polymerise and cure the adhesives and form a monobloc module,
and at least one electronic power component is mounted, in particular by welding, on the conductive bar so that its contacts rest on the printed circuit board and on one face of the power-conducting bar, as well as electronic components with a reduced heat dissipation on the printed circuit board.
